(19) United States
(12) Patent Application Publication
(10) Pub. No.: US 2003/0028705 A1
(43) Pub. Date: Feb. 6, 2003

(54) Computer device based on associative memory

(76) Inventor: Yutaka Arima, Iizuka-shi (JP)

Correspondence Address: Finnegan, Henderson, Farabow,, Garrett & Dunner, L.L.P., 1300 I Street, N.W., Washington, DC, 20005-3315, US

(21) Appl. No.: 10/086,544

(22) Filed: Mar. 4, 2002

(30) Foreign Application Priority Data
Mar. 5, 2001 (JP) 2001-60514

(51) Int. Cl. G11C 5/00; G06F 12/00; G06E 1/00; G06E 3/00; G06N 3/02; G06G 7/00; G06F 15/18; G06F 12/14; G06F 12/16; G06F 13/00; G06F 13/28

(52) U.S. Cl. 711/100; 711/1; 711/101

(57) ABSTRACT

The associative memory-based computer includes at least one associative memory, a plurality of associative data memories capable of temporarily holding input or output data of the associative memory, and a value judgement device receiving part of the data held in the associative data memory. The associative memory is formed of a chaotic neural network. The associative data memories include a first associative data memory sending/receiving data directly to/from the associative memory, and a plurality of second associative data memories sending/receiving data to/from the associative memory via the first associative data memory.

### BACKGROUND OF THE INVENTION

1. Field of the Invention

The present invention generally relates to a computer based on an associative memory (hereinafter, referred to as “associative memory-based computer”). More particularly, the present invention relates to an associative memory-based computer which enables implementation of a device efficiently performing intuitive information processing similar to a human thinking process.

2. Description of the Background Art

Intuitive information processing such as pattern recognition, context association, combinatorial optimization or the like, which is difficult to carry out with conventional information processing devices (computers), is a technique indispensable for smooth communication between information processing machines and human beings. Such a technique is expected to make a breakthrough for the machines to be fitted into and utilized in the society without sense of discomfort. To efficiently carry out such intuitive information processing, a brain-type computer based on a completely new architecture modeled after the manner of processing information by the brain has been studied vigorously, and development of a brain-type computer hardware of a level standing up to practical use is strongly demanded.

Since invention and practical application of a semiconductor integrated circuit in the early 1970s, with rapid advancement of manufacturing techniques of large scale integrated circuits (LSI) such as microprocessing units (MPU) and microprogram control units (MCU), a program driven-type computer, which is most common at present, has undergone successful downsizing, improvement in performance, speeding up, reduction in power consumption and cost, and increase in reliability. Such a program driven-type computer, now incorporated in any kind of electronic equipment, has become indispensable to our lives. The program driven-type information processing machine as typified by a von Neumann-type computer is formed with a data storing function (a memory portion) and a data processing (e.g., computing) function (a processor portion). It carries out various kinds of information processing by setting a program expressing a processing procedure in accordance with a processing content.

Such a conventional-type computer has rapidly widespread along with the progress of the semiconductor integrated circuit, mainly because of its ease of fabrication and applicability to wide purposes. More specifically, it is easy to fabricate because of its functional configuration with the data processing portion and the memory portion being clearly separated from each other. In addition, it adopts a step-by-step time serial processing scheme, so that it goes quite well with a binary digital circuit that is advantageous to data holding and synchronous processing expression of linear operation or the like. Simplicity in designing because of its switch circuit (threshold circuit) and operational stability of the large-scale circuit have enabled synergistic progress of such a conventional-type computer with the semiconductor integrated circuit technology. The applicability to wide purposes means that it can be adapted to various kinds of applications according to its capability, with its basic structure remained unchanged. Even in the initial stage of advent of an integrated circuit when hardware was poor in performance, it could be put into practical use with reasonable processing speed and device size. As such, the conventional-type computer has maintained its basic structure since its advent to date, and the range of its uses has rapidly widened only with its quantitative improvement in device size, processing speed, power consumption and the like, and partial improvement in mechanism. This fact alone proves its excellent applicability to wide purposes.

However, there remains a field of information processing that cannot be efficiently represented with such a highly applicable computer. It is so-called intuitive information processing, including pattern recognition, context association, combinatorial optimization and the like, which human beings do unconsciously. It is quite difficult for a conventional-type computer to represent such intuitive information processing efficiently at the level standing up to practical use. This is for the reasons that the conventional-type computer architecture has a characteristic in principle that a processing procedure should be expressed by a program, and that the computer of this type is inefficient in performing a large amount of operations or non-linear processing at high speed. By nature, it would be extremely difficult to write a program expressing the intuitive processing unconsciously done by the human beings as algorithm. Furthermore, if a neural network model is programmed and simulated as means for the intuitive information processing, it will require a huge amount of operations, which would be almost impossible to be processed in a practical time period with a conventional serial processing architecture.

The key to an increased prevalence of information technology (IT) in the future will be a technique with which more people can use electronic equipment more comfortably, and implementation of smooth communication function between human beings and machines. The intuitive information processing like pattern recognition, context association and combinatorial optimization is an indispensable technique for an information processing machine to implement unrestrained communication with a human being. Such a technique is expected to make a breakthrough that will allow a machine to be fitted into and utilized in the society without sense of discomfort. To efficiently carry out such intuitive information processing, a brain-type computer based on a completely new architecture modeled after the manner of processing information by the brain has been studied vigorously, and development of a brain-type computer hardware of a level standing up to practical use is strongly demanded.

With the increasing expectations on practical utilization of a new type computer for intuitive information processing, research and development for putting it into hardware have been made. To date, however, only associative memories like various neural network LSI, and functional units implementing pattern discrimination, learning function and others, have been developed and made by trial.

Based on the foregoing, now devised by incorporating those functional units as components and combining them appropriately is construction of a basic architecture of an associative memory-based computer, as a computer (information processing machine) including a control sequence, that enables implementation of a device efficiently performing intuitive information processing similar to the human thinking process. In particular, a hardware configuration of an associative memory-based computer having a neural network associative memory as its main functional body and capable of spontaneously performing context association, and a control sequence thereof are proposed.

### SUMMARY OF THE INVENTION

An object of the present invention is to provide an associative memory-based computer capable of efficiently performing intuitive information processing similar to a human thinking process.

According to the present invention, the associative memory-based computer includes at least one associative memory, a plurality of associative data memories that can temporarily hold input or output data of the associative memory, and a value judgement device that receives part of the data held in the plurality of associative data memories.

Further, the associative memory-based computer of the present invention is characterized in that the associative memory is formed with a chaotic neural network.

Further, the associative memory-based computer of the present invention is characterized in that the associative memory includes a first associative data memory that sends/receives data directly to/from the associative memory, and a plurality of second associative data memories that send/receive data to/from the associative memory via the first associative data memory.

Further, the associative memory-based computer of the present invention is provided with a function to modulate a threshold value of a neuron forming associative data in accordance with its fired frequency.

Further, the associative memory-based computer of the present invention is characterized in that the modulation of the threshold value is performed by decreasing the threshold value of the neuron in proportion to the fired frequency of the relevant neuron.

Further, the associative memory-based computer of the present invention is characterized in that the value judgement device receives part of the data in the first associative data memory and evaluates whether an output result associated in the associative memory is a desired result or answers for a purpose, and in that an output signal from the value judgement device is used to control whether to transfer the associative data held in the first associative data memory to the second associative data memory.

Further, the associative memory-based computer of the present invention is characterized in that the value judgement device receives part of the data in the plurality of second associative data memories and evaluates whether the plurality of associative data held in the respective second associative data memories are consistent with each other, and in that an output signal of the value judgement device is used to control whether to transfer the associative data held in the second associative data memories to the first associative data memory.

Further, the associative memory-based computer of the present invention includes: a chaotic associative memory having a raw neuron group as a collection of raw neurons implementing actions with the outside world like sensory organs and muscles, and a symbol neuron group as a collection of symbol neurons serving as sources of information processing within the computer; a first associative data memory directly connected to the symbol neuron group in the chaotic associative memory and having a function to temporarily hold a symbol pattern represented by states of neuron signals of the symbol neuron group; a plurality of second associative data memories connected to the first associative data memory and having a function to hold a plurality of patterns of the symbol pattern on the first associative data memory as required; a first value judgement device receiving some of the signals of the first associative data memory and outputting a signal for determining whether the pattern on the first associative data memory is worth holding on the second associative data memory; and a second value judgement device receiving part of the respective data in the second associative data memories and having a function to determine whether the plurality of symbol patterns held in the second associative data memories are consistent with each other.

Further, the associative memory-based computer of the present invention is characterized in that it is formed with a plurality of chaotic associative memories. Each associative memory has its raw neuron group connected with raw pattern signal inputs from sensory organs like eyes and ears or raw pattern signal outputs to muscles of vocal muscle, hands and legs or secretory organs, in accordance with its specific role, to implement an interface with the outside world. Every chaotic associative memory includes a symbol neuron group representing an abstractive state. The symbol neuron group includes, between itself and a working memory portion as will be described below, a portion where a state pattern signal common to all the memories is input, a portion where a common symbol pattern is input/output, and a portion where a symbol pattern specific to each memory is input/output. Each associative memory includes: an associative memory portion which relates a raw pattern from various sensory organs to an abstractive, specific symbol pattern formed from the common symbol pattern through learning, to implement complicated association including correlation between the memories; a working memory portion formed with a symbol stage which has a function to temporarily store and hold the common symbol pattern, all the specific symbol patterns and the state pattern from the associative memory portion, and also has a function to temporally integrate an activation value of each symbol neuron to modulate its firing threshold value in accordance with the integral, a plurality of working memories which have a function to hold pattern information held in the symbol stage for a certain period of time, and a function to have a value, for each of the plurality of working memories, indicating the degree of activation with respect to the information held therein, the degree of activation having a mechanism to be attenuated with a certain time constant and at the same time to be increased/decreased by a prescribed amount in accordance with a condition of a control sequence as will be described below, and a control sequencer which generates a state pattern signal for use in defining directivity of association (whether to abstract or objectify), invalidation of each input information, invalidation of each associative output, directivity of each symbol signal (input or output) and others in accordance with an externally supplied object signal, and applies the signal commonly to the respective associative memories; and a value judgement network portion formed with a result determination network which receives some of the pattern signals of the symbol stage in the working memory portion and has a function to perform value evaluation of, e.g., whether a result associated in the associative memory portion answers for a purpose, and determine whether to transfer the symbol pattern being held newly to the working memory, and a consistency determination network which receives some of the pattern signals from the working memories and has a function to determine whether the plurality of symbol patterns held in the working memories are consistent with each other, and, according to the value evaluation, allow the control sequence to develop into an operation for actually controlling a movement or the like, each determination network being formed with a hierarchy-type neural network having a function to improve its value judgement capability through learning, and value signals as their outputs being applied to the control sequencer in the working memory portion.

Alternatively, the associative memory-based computer of the present invention is provided with an associative memory portion including a plurality of chaotic associative memories. Each chaotic associative memory has a symbol neuron group representing an abstractive state, and a raw neuron group connected with raw pattern signal inputs from sensory organs like eyes and ears or raw pattern signal outputs to muscles of vocal muscle, those of hands and legs or secretory organs, in accordance with its specific role, to implement an interface with the outside world. It also relates a raw pattern from various sensory organs to an abstractive, specific symbol pattern formed from a common symbol pattern through learning, to implement complicated association including correlation between the chaotic associative memories. The associative memory-based computer is further provided with a working memory portion and a value judgement network portion. The working memory portion includes: a symbol stage having a function to temporarily store and hold the common symbol pattern, all the specific symbol patterns and a state pattern from the associative memory portion and also having a function to temporally integrate an activation value of each symbol neuron to modulate a firing threshold value in accordance with the integral; a plurality of working memories having a function to hold pattern information held in the symbol stage for a prescribed period of time; and a control sequencer generating a state pattern signal for use in defining directivity of association, invalidation of each input information, invalidation of each associative output, directivity of each symbol signal and others in accordance with an externally supplied object signal, and applying the signal commonly to the respective associative memories. The value judgement network portion includes: a result determination network which receives some of the pattern signals of the symbol stage in the working memory portion, and has a function to evaluate at least whether a result associated in the associative memory portion answers for a purpose, and determine whether to transfer the symbol pattern being held newly to the working memory; and a consistency determination network which receives some of the pattern signals from the working memories, and has a function to determine whether the plurality of symbol patterns held in the working memories are consistent with each other and, according to the value evaluation, allow a control sequence to develop into an operation for actually controlling a movement or the like. Each symbol neuron group includes, between itself and the working memory portion, a portion where a state pattern signal common to all the memories is input, a portion where a common symbol pattern is input/output, and a portion where a specific symbol pattern for each memory is input/output. The plurality of working memories have a function to have a value, for each working memory, indicating the degree of activation with respect to the information held therein, and the degree of activation has a mechanism to be attenuated with a certain time constant and at the same time to be increased/decreased by a prescribed amount in accordance with a condition of the control sequence. Each of the result determination network and the consistency determination network is formed with a hierarchy-type neural network having a function to improve the value judgement capability through learning, and value signals as outputs from the result determination network and the consistency determination network are applied to the control sequencer in the working memory portion.

Further, in the associative memory-based computer of the present invention, the directivity of the association indicates whether to abstract or objectify the association.

Further, in the associative memory-based computer of the present invention, the directivity of each symbol signal indicates whether the common symbol pattern is an input or an output with respect to each chaotic associative memory.

As such, the associative memory-based computer of the present invention is capable of efficiently carrying out so-called intuitive information processing such as pattern recognition, context association, combinatorial optimization or the like, which is unconsciously done by human beings but difficult to be done using a conventional computer. Its base of information processing is associative processing using the associative memories, so that it can perform association similar to the human beings. Setting of associative correlation through learning is also possible. Accordingly, the associative memory-based computer of the present invention, with its simple functional configuration and control flow, enables flexible and easy implementation of unrestrained communication between information processing machines and human beings.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic diagram showing the most fundamental configuration of an associative memory-based computer of the present invention.

FIG. 2 is a schematic diagram showing exemplary abstractive categories of a pattern to be processed by the associative memory-based computer of the present invention.

FIGS. 3 and 4 are schematic diagrams illustrating the mechanism of context association in the associative memory-based computer of the present invention.

FIGS. 5-8 are first through fourth schematic diagrams illustrating a basic sequence of the present invention.

FIG. 9 is a block diagram showing a configuration of a first associative data memory of the present invention.

FIG. 10 is a block diagram showing an elemental circuit forming the first associative data memory of the present invention.

FIG. 11 is a circuit diagram showing a configuration of a neuron circuit within the associative memory of the present invention.

FIG. 12 is a schematic diagram showing a configuration of an associative memory-based computer according to an embodiment of the present invention.

FIG. 13 is a flow chart illustrating an embodiment of a control sequence in the associative memory-based computer of the present invention.

### DESCRIPTION OF THE PREFERRED EMBODIMENTS

(Principal Components)

Firstly, principal components or minimum essentials of a computer based on an associative memory (hereinafter, “associative memory-based computer”) will be described. Here, a chaotic neural network is employed as the associative memory. Basics of the chaotic neural network and chaotic association using the same are described by Fumiyuki Takahashi in “Chapter 7: Chaos and Memory,” Chaos Seminar, edited by Kazuyuki Aihara, Kaibundo, April, 1994 (hereinafter, also referred to as “Reference 1”) and by Masaharu Adachi in “Chaos and Associative Memory,” Computer Today 1999.7, No. 92, Science Inc., July, 1999 (hereinafter, also referred to as “Reference 2”).

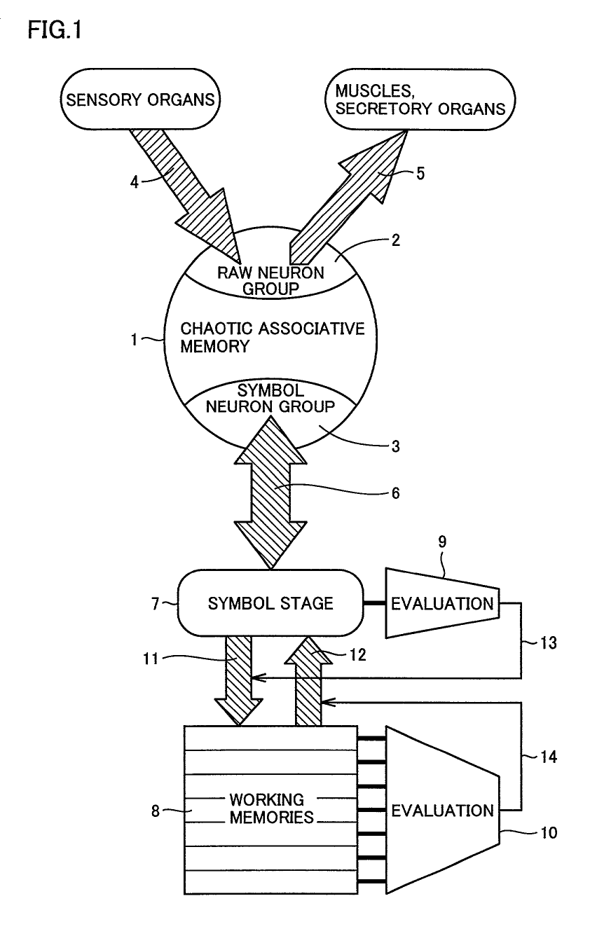

FIG. 1 shows the most fundamental functional configuration of an associative memory-based computer according to the present invention. As shown in FIG. 1, a chaotic associative memory 1 formed of a chaotic neural network includes raw neurons implementing actions 4, 5 with the outside world like sensor organs and muscles, and symbol neurons serving as sources of information processing within the computer. A mass of the raw neurons is herein called a raw neuron group 2. Those neurons are named “raw” as they represent pattern information of the outside world essentially “raw” (with almost no processing). A mass of the symbol neurons is called a symbol neuron group 3. Those neurons are named “symbol” as they have associative correlation with the raw pattern represented by the raw neuron group and represent an abstracted pattern with respect to the raw pattern.

States of neuron signals of the symbol neuron group (signal pattern) represent a symbol pattern. A first associative data memory 7 (hereinafter, referred to as “symbol stage”) directly connected to the symbol neuron group of the associative memory has a function to temporarily hold the symbol pattern. A plurality of second associative data memories 8 (hereinafter, referred to as “working memories”) connected to symbol stage 7 have a function to hold different patterns of the symbol pattern on symbol stage 7 as required. A value judgement device 9 receives some of the signals from symbol stage 7, and outputs a signal 13 determining whether the pattern on symbol stage 7 is worth holding on working memory 8. Another value judgement device 10 receives part of the data held in respective working memories 8. The device 10 has a function to determine whether the plurality of symbol patterns held in working memories 8 are consistent with each other.

(Operational Principles)

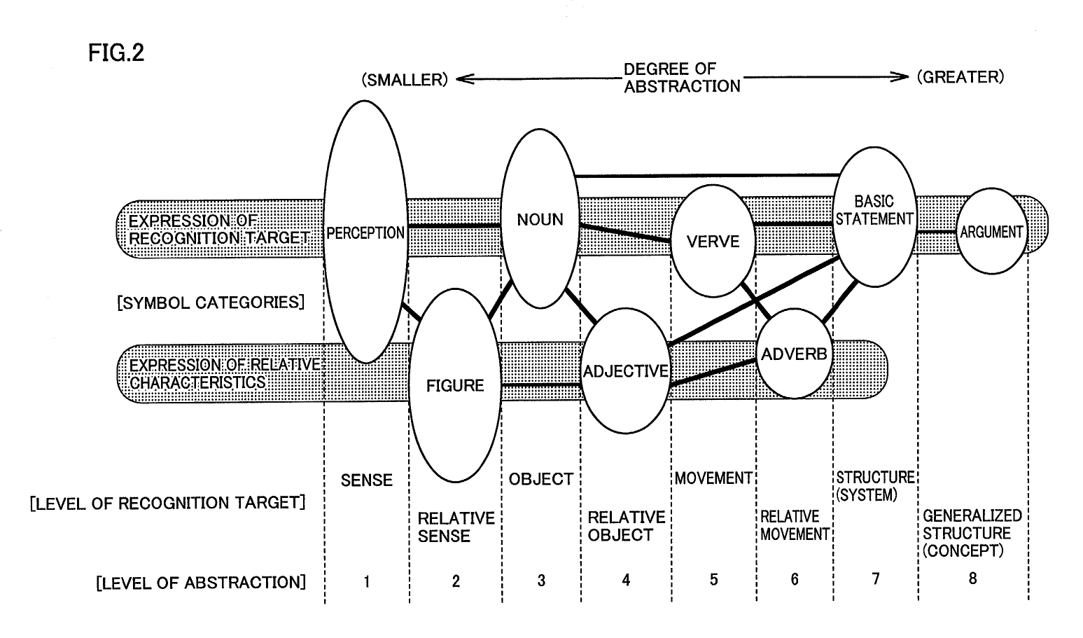

Fundamental principles of operation of the associative memory-based computer will now be described. This computer uses the symbol patterns represented by the symbol neuron group in the associative memory as the base elements (source data) in all the information processing. The symbol patterns can be classified into symbol categories as shown in FIG. 2, for example. Herein, the symbol categories are sets of the symbol patterns grouped for different recognition target levels. In this example, there are eight categories according to the degrees of abstraction of the patterns.

Respective circles shown in FIG. 2 represent symbol pattern sets belonging to respective symbol categories, which are, in ascending order of the degree of abstraction, perception, figure, noun, adjective, verb, adverb, basic statement, and argument. Bold lines connecting the categories represent associative correlation between the pattern sets. That is, it is assumed that there is associative correlation only between the pattern set elements of the categories connected by the bold lines. In this example, the symbol categories of perception, noun, verb, basic statement and argument are employed to express a recognition target. The symbol categories of figure, adjective and adverb are employed to express its relative characteristics.

For example, it can be interpreted that the symbol category of basic statement is used for an expression to recognize a structure of a system formed of a plurality of targets, while the symbol category of argument is used for an expression to recognize a generalized concept of the structure of the system expressed by the basic statement. In the associative memory-based computer, a conceivable way to specifically distinguish these symbol icategories as information will be to provide as a portion of the symbol neuron group a neuron group dedicated to represent the degree of abstraction, and to register, when learning patterns, the pattern states corresponding to the specific levels of abstraction. Using this abstraction level pattern represented by the neuron group dedicated to represent the degree of abstraction, it becomes possible to identify a category of the symbol pattern associated, and to determine whether the associated result answers for a purpose. A signal from the neuron group dedicated to represent the degree of abstraction can be used as part of the input of value judgement device 9.

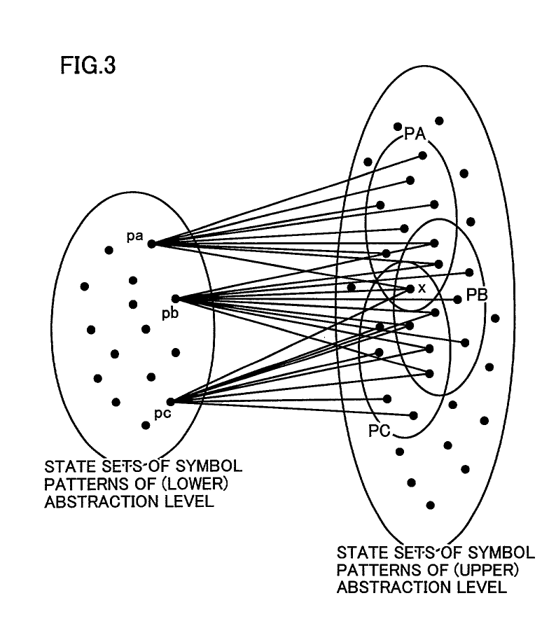

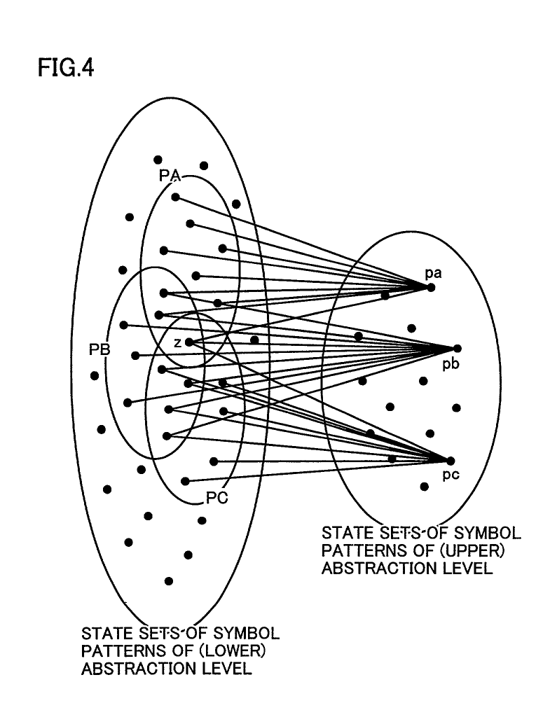

The principle for performing context association is now described with reference to FIGS. 3 and 4. Here, it is assumed that the chaotic associative memory prestores, through learning, the associative correlation between symbol patterns of different abstraction levels as described above. FIG. 3 illustrates the case where the symbol patterns pa, pb, pc of the lower abstraction level are used to associate the symbol patterns of the upper abstraction level.

Firstly, symbol pattern pa is used as the source of association (pattern initial state) to associate a symbol pattern in its upper level. At this time, by virtue of the characteristic of the chaotic associative memory, two or more patterns are retrieved from among a plurality of upper-level symbol patterns included in a state set PA having associative correlation with pattern pa, through dynamic transition therein. Next, symbol pattern pb is used as the source of association to perform chaotic association of upper-level symbol patterns in a state set PB in the same manner. Likewise, chaotic association of upper-level symbol patterns in a state set PC is carried out using symbol pattern pc as the source of association. If fired frequencies of respective neurons are accumulated as specific activation values through such associating processing, i.e., if each neuron is made more likely to fire in proportion to its fired frequency, then it is expected that a state pattern x as an element of the product set of the state sets PA, PB, PC is most likely to occur ultimately. That is, in the course of successive association based on symbol patterns pa, pb and pc, probability of occurrence of an element in the product set of such association increases, and thus, the upper-level symbol pattern x having associative correlation with all the states of pa, pb and pc is associated ultimately.

In the case where a symbol pattern in a lower abstraction level is to be associated from those in an upper level, as shown in FIG. 4, a symbol pattern z is ultimately associated in the same manner. As such, the principle to use a plurality of state patterns as the sources of association to screen and associate the symbol pattern that is an element of the product set of the associative correlation can be employed for implementation of so-called context association. Here, the direction of association, i.e., whether it is from a lower level to an upper level of abstraction or vice versa, can be controlled by forming a symbol neuron defining the direction of association through learning, and by providing it with a signal as a boundary condition at the time of association.

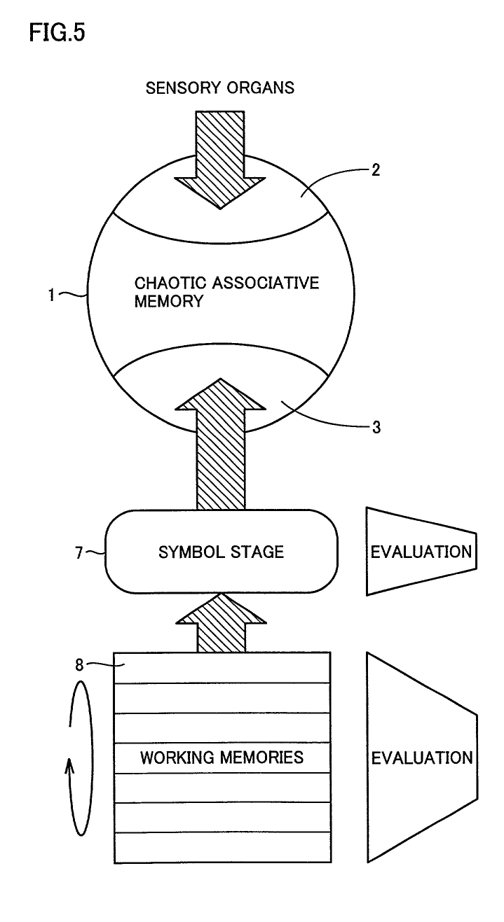

A processing procedure for performing the context association based on the principle shown in FIGS. 3 and 4 will now be described schematically with reference to FIGS. 5-8. Specifically, a simple flow of signals and basic operations will be described. FIG. 5 illustrates an operation in the process where association is carried out using patterns as the sources of association. The working memories have a function to store and hold a plurality of symbol patterns. It is assumed that a plurality of patterns, e.g., pa, pb, pc, serving as the sources of association are held in advance in the working memories.

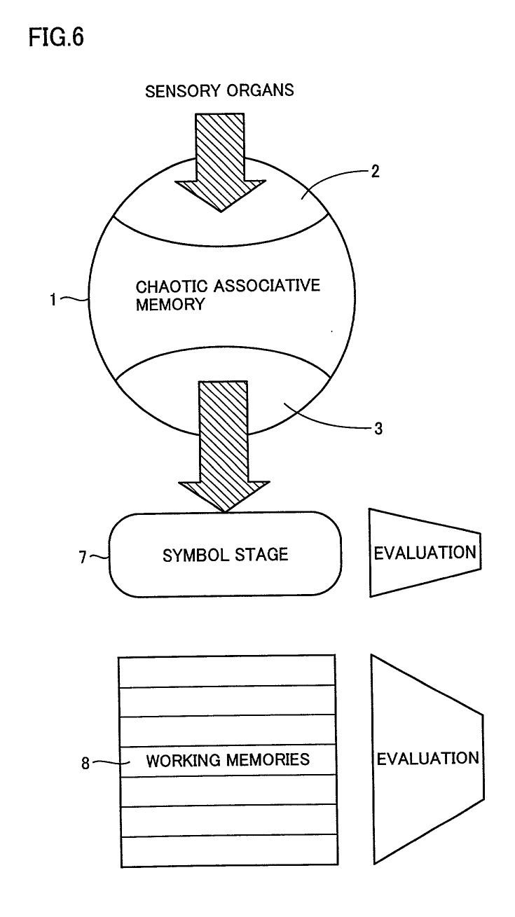

Firstly, symbol pattern pa within working memory 8 is transferred to symbol stage 7 and temporarily held therein. This symbol pattern pa on symbol stage 7 is provided to the associative memory 1 as an initial state pattern of its symbol neuron group to be employed as the source of association. Next, associative memory 1 starts chaotic association using the source pattern of association provided to the symbol neuron group 3 and a raw pattern being input at that time as initial boundary conditions of association. In some cases, the raw pattern information from the outside may be intentionally blocked off partially or entirely using a specific control signal applied to associative memory 1, or a mechanism enabling control of the external information to some extent may be provided. Through this chaotic association, a plurality of symbol patterns are associated. Every time a symbol pattern is associated, each neuron in symbol stage 7 accumulates its fired frequency, as shown in FIG. 6.

When the association using symbol pattern pa as its source is through, working memory 8 transfers symbol pattern pb to symbol stage 7 for execution of association using symbol pattern pb as its source. Likewise, chaotic association is conducted successively using symbol patterns within working memories 8 as the sources of association. When the association using all the source patterns is completed, an associative symbol pattern x which eventually occurred most stably is held on symbol stage 7 temporarily.

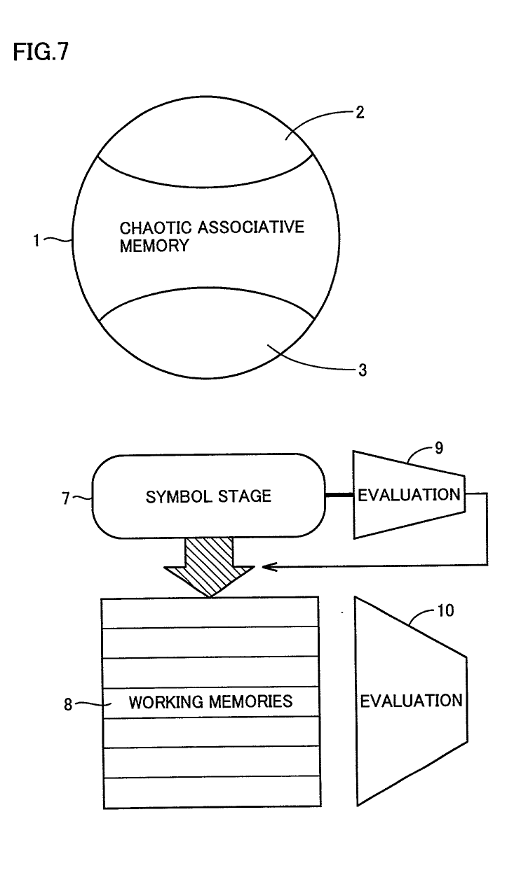

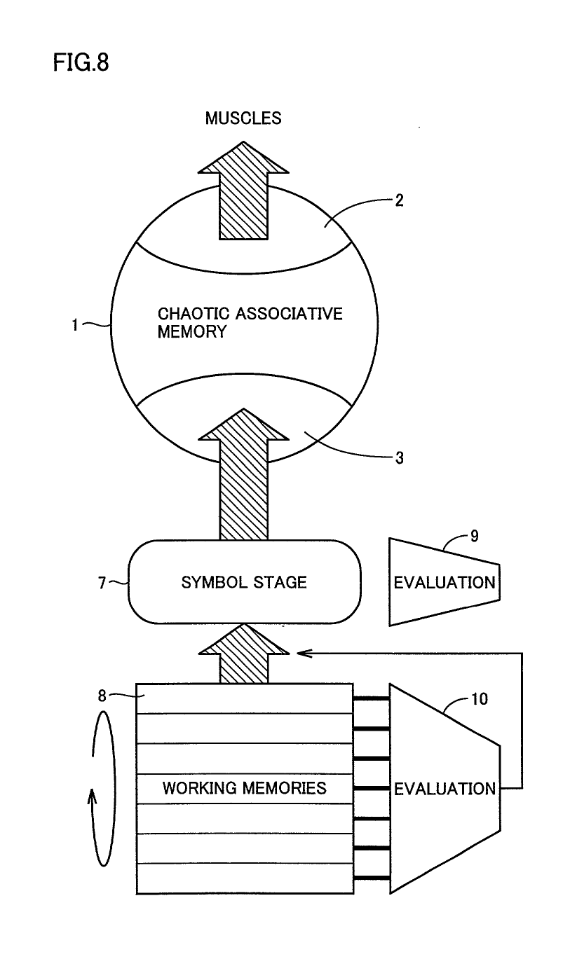

Next, as shown in FIG. 7, value judgement device 9 evaluates the symbol pattern held in symbol stage 7. The pattern is transferred to the working memory if it is determined worth holding. After completion of the series of associative processing shown in FIGS. 5-7 for all the source patterns prepared in working memories 8, if the associative symbol pattern finally retrieved is determined satisfactory enough to fulfill the purpose, then the process goes to an output operation shown in FIG. 8. If the result of association is determined unsatisfactory, the association operation shown in FIGS. 5-7 is repeated with a new condition or with a new source pattern.

In the state shown in FIG. 8 that is achieved when the result of association is determined satisfactory, evaluation is made as to whether the plurality of symbol patterns stored in the working memories are consistent with each other. If it is determined no problem, each symbol pattern to be an answer is called up to symbol stage 7, and provided to the symbol neuron group of associative memory 1. Associative memory 1, using it as the boundary condition, outputs signals to muscles and/or secretory organs to implement actions with respect to the outside world. The value judgement at respective value judgement devices 9, 10 can implement associative processing in conformity with a purpose set up for the computer when various parameters are adjusted according to the intended purpose.

(Functional Configuration)

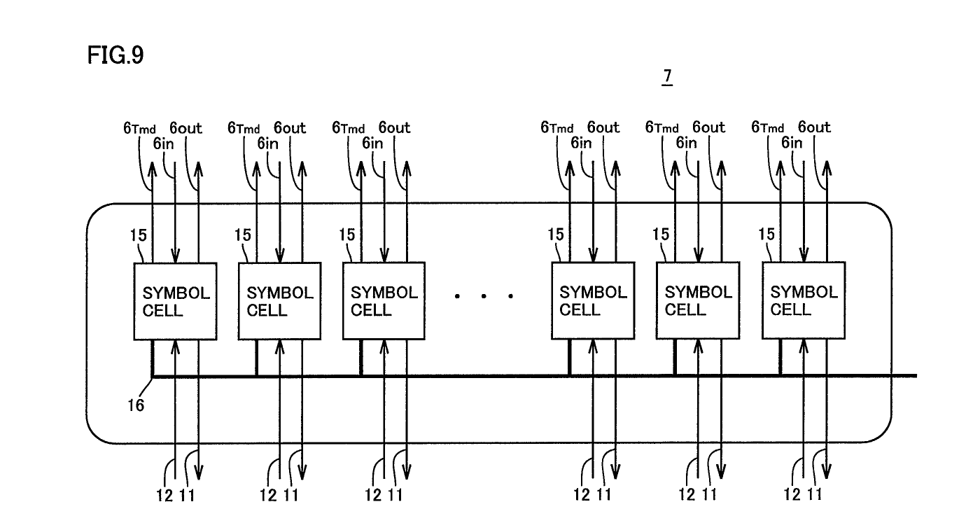

Hereinafter, firstly, an example of functional configuration implementing a function necessary for enabling the context association described above, i.e., a function to make respective neurons more likely to fire in proportion to their fired frequencies, is described with reference to FIGS. 9-11. An exemplary configuration of an electronic circuit implementing a neural network is described by Yutaka Arima in “Chapter 3: Higher Integration of Neural Network with Learning Function”, Study of Associative Memory Analog Neural Network LSI with Learning Function, Doctoral Thesis of University of Tokyo, January 1998 (hereinafter, also referred to as “Reference 3”), which is incorporated herein by reference.

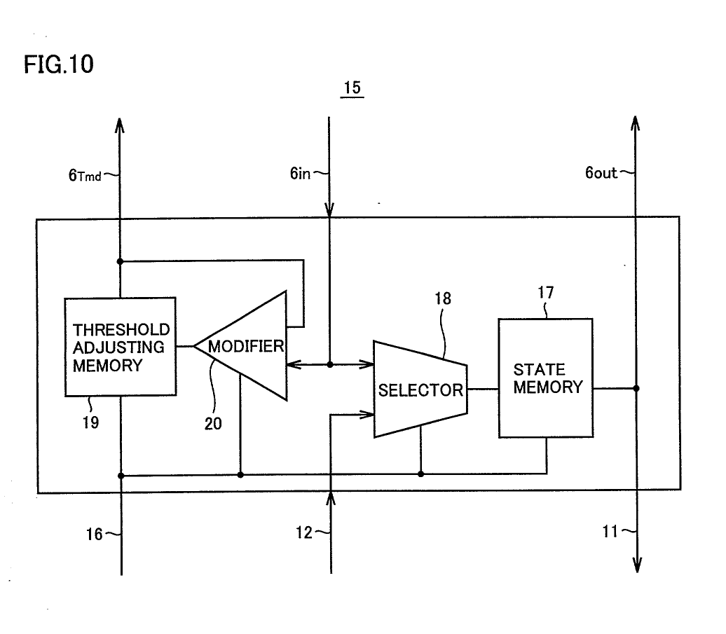

FIG. 9 shows an exemplary configuration of symbol stage 7. Symbol stage 7 has a function to temporarily hold a symbol pattern represented by the symbol neuron group in the associative memory, and includes a plurality of symbol cells 15 as illustrated in FIG. 10. The symbol cells are prepared corresponding to respective symbol neurons in the associative memory connected thereto, and are commonly provided with a control signal 16. As shown in FIG. 10, symbol cell 15 includes a state memory 17 which holds a state of the corresponding symbol neuron, a selector 18 which selects, as an input of the state memory, a corresponding state signal of the working memory or a corresponding signal of the associative memory, a memory for adjustment of threshold value, or, threshold adjusting memory 19 which is for modulating the degree of activation of the corresponding symbol neuron, and a modifier 20 for modulating the value of the threshold adjusting memory.

State memory 17 may be a common 1-bit digital latch circuit if the state of neuron is binary (fired or unfired). Threshold adjusting memory 19 may hold an analog voltage in a capacitor, and modifier 20 may be a charge pump circuit or the like (see Reference 3).

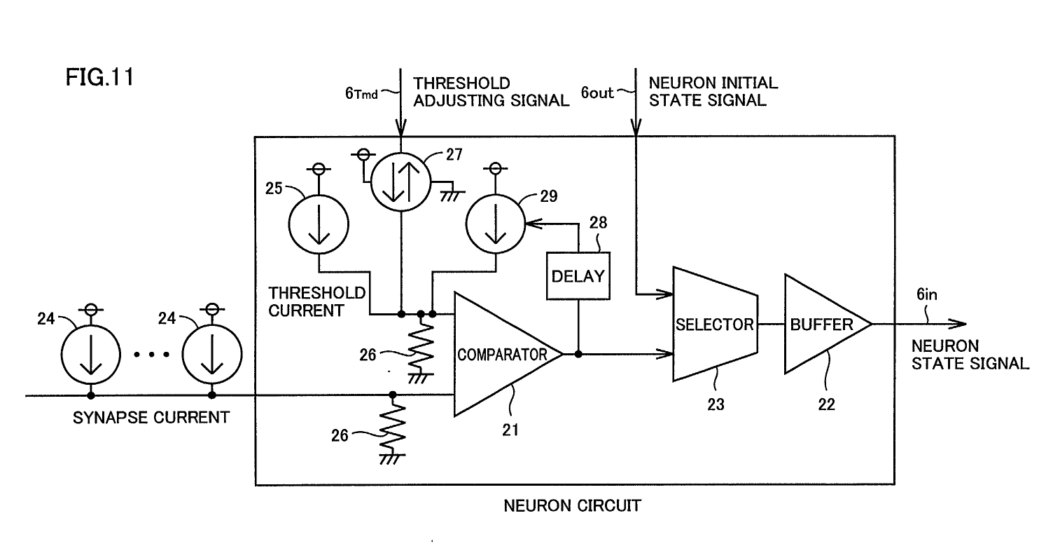

FIG. 11 shows an exemplary circuit configuration of the symbol neuron in the associative memory. The neuron circuit includes a comparator 21, a delay circuit 28 which delays an output signal of the comparator, a selector 23 which selects the output signal of the comparator or a state signal 6out output from a corresponding symbol cell in the symbol stage, a buffer 22 for outputting a state signal of the neuron, a threshold current source 25 which presents a threshold value of the neuron, two resistors 26 which convert the threshold current and a synapse current to respective voltages, a threshold adjusting current source 27 which presents a threshold adjusting current by a threshold adjusting signal 6Tmd output from the corresponding symbol cell, and an absolute non-responsive period representing current source 29 which responds to the state signal after some delay and substantially increases the threshold value during the time period to suppress firing so as to implement the absolute non-responsive period of the neuron that is necessary for representation of the chaotic neural network.

Comparator 21 receives, as a current, synapse signals from synapses connected to the relevant neuron, all of which are converted to a voltage by resistor 26. The comparator compares the obtained voltage with an essential threshold voltage derived from the threshold current and the threshold adjusting current, and outputs a firing signal when the signals from the synapses exceeded a substantial threshold value. The signal is provided to absolute non-responsive period representing current source 29 after a prescribed delay via delay circuit 28, and the essential threshold value is increased to cancel the fired state. The absolute non-responsive period of the neuron can be controlled by adjusting this delay time, so that the associative retrieval behavior of the chaotic neural network can be adjusted. Selector 23, at the start of association, selects the Gout signal from the symbol cell to fix the symbol pattern to the initial state with the associative source pattern data. As such, using the circuit configurations shown in FIGS. 9-11, the function to make respective neurons more likely to fire in proportion to their fired frequencies in the associative process can be implemented.

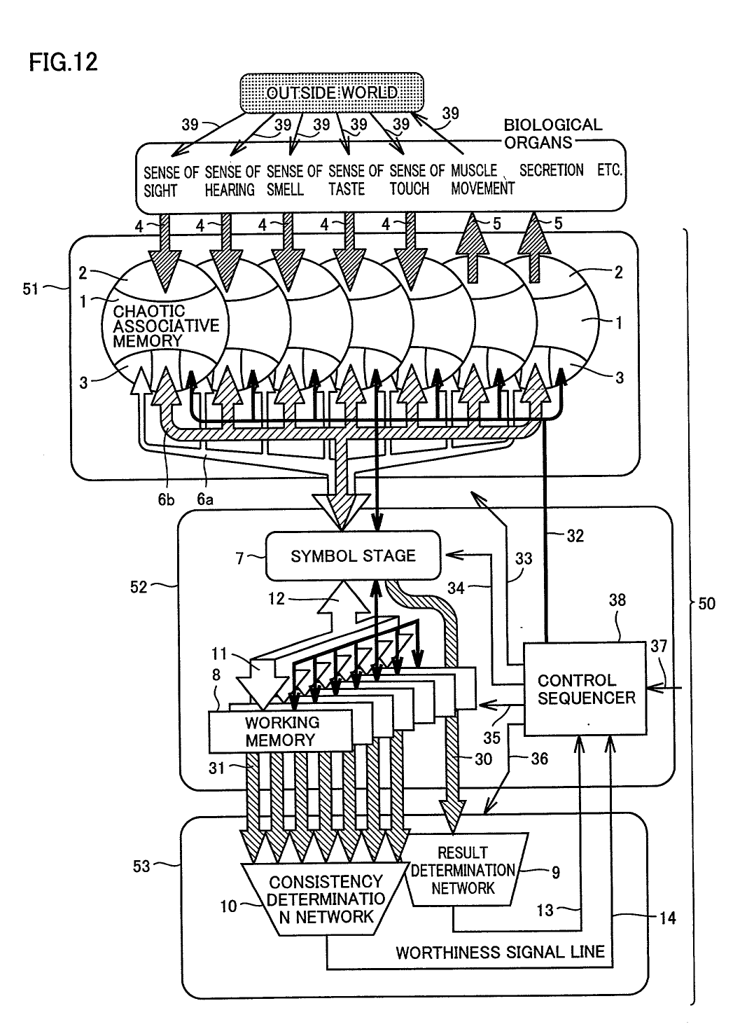

Next, an exemplary functional configuration of a more common associative memory-based computer will be described. FIG. 12 shows an associative memory-based computer 50 provided with a typical functional configuration. Associative memory-based computer 50 can be divided into three functional portions according to their respective functional structures: an associative memory portion 51, a working memory portion 52, and a value judgement network portion 53.

Associative memory portion 51 is formed with a plurality of chaotic associative memories 1. Each associative memory 1 has a raw neuron group connected with raw pattern signal inputs from sensory organs like eyes and ears, or raw pattern signal outputs to muscles, such as vocal muscle or those of hands and legs, or secretory organs, depending on its specific role, to implement an interface with the outside world. Chaotic associative memory 1 also has a symbol neuron group representing an abstractive state. The symbol neuron group includes, between itself and working memory portion 52, a portion where a state pattern signal common to all the memories is input, a portion where a common symbol pattern 6b is input/output, and a portion where a specific symbol pattern 6a for each memory is input/output.

Each associative memory 1 relates a raw pattern from various sensory organs with an abstractive, specific symbol pattern formed based on the common symbol pattern through learning, to implement complicated association including correlation between the memories. The state pattern signal 32 being commonly applied to respective associative memories 1 is generated from a control sequencer 38 in working memory portion 52, which is introduced for control of directivity of information processing in this associative memory-based computer 50. State pattern signal 32 is used for defining directivity of association (to abstract or objectify), invalidation of each input information, invalidation of each associative output, directivity of each symbol signal (input or output) and others.

In the case of the organic brain, the interface with the other sites is implemented by sensory organs like eyes and ears, muscles moving mouth, hands and legs, and secretory organs of internal substances like hormones, via nerve bundles. In the case of the organism, the brain itself expresses a will (the content or directivity of the desired information processing), and a special function for controlling the brain is unnecessary. To technically utilize the brain-type computer as a machine, however, it is necessary to incorporate a control capability corresponding to the will. Thus, in the proposed associative memory-based computer, the control sequencer 38 is introduced which generates state pattern signal 32 for control of the directivity of the information processing according to an externally supplied object signal 37. An example of the control flow will be described later.

Working memory portion 52 includes a symbol stage 7, a plurality of working memories 8, and the control sequencer 37 for control of all the functions. Symbol stage 7 has a function to temporarily store and hold common symbol pattern 6b, all the specific symbol patterns 6a and the state pattern from associative memory portion 51 (corresponding to state memory 17 shown in FIG. 10), a function to temporally integrate an activation value for each symbol neuron (corresponding to threshold adjust memory 19 in FIG. 10), and a function to modulate a firing threshold value in accordance with the integral (corresponding to modifier 20 in FIG. 10). Introduction of these functions enables the context association. Working memories 8 have a function to hold pattern information held in symbol stage 7 for a certain period of time, and also have a function to have values indicating the degrees of activation (degrees of validity) for information held in the respective working memories. The degree of activation (degree of validity) has such a mechanism that it is attenuated with a certain time constant and, at the same time, is increased/decreased by a prescribed amount in accordance with a condition of the control sequence.

Value judgement network portion 53 includes a result determination network 9 which inputs some of pattern signals 30 of symbol stage 7 in working memory portion 52, and a consistency determination network 10 which inputs some of pattern signals 31 from the working memories. Each determination network is formed of a hierarchy-type neural network having a function to improve the value judgement capability through learning. The value signals being their outputs are applied to control sequencer 38 in the working memory portion.

Result determination network 9 evaluates, e.g., whether the result associated in the associative memory portion answers for a purpose, and determines whether the symbol pattern held should be newly transferred to working memory 8. Consistency determination network 10 determines whether the plurality of symbol patterns held in working memories 8 are consistent with each other, and also has a function, according to the value evaluation, to cause a control sequence to develop into an operation for actually controlling a movement or the like.

Next, a fundamental control sequence for context association or autonomous associative development by the associative memory-based computer of this configuration will be described in brief.

(Control Sequence)

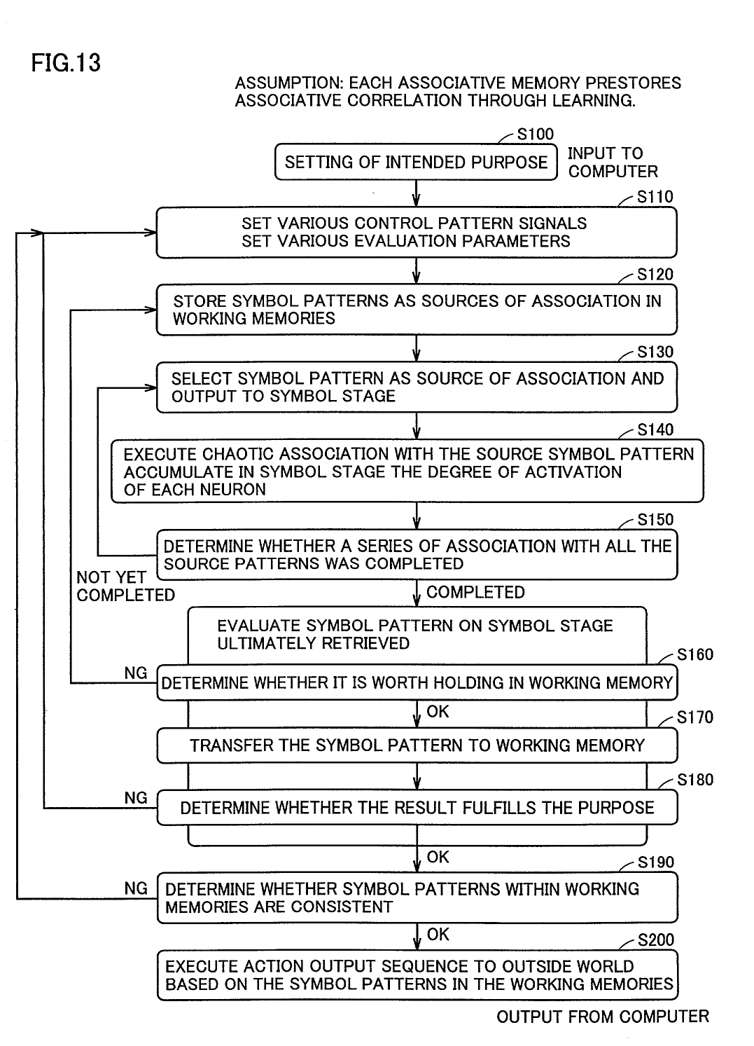

FIG. 13 shows a flow of the basic control sequence of autonomous context association carried out by the associative memory-based computer having the functional configuration described above. Firstly, a purpose should be set and designated to the computer (step S100). Here, the control sequence is described in connection with a relatively clear purpose setting.

In the purpose setting, the abstraction level corresponding to the symbol category of the required answer is made clear. Next, the symbol pattern currently available is examined for its symbol category, and an associative correlation path to reach the symbol category of the answer is established. Based on the necessary associative correlation path, various control pattern signals and values of evaluation parameters are set (step S110). The control pattern signals include a signal for defining directivity (to the upper level or to the lower level) of association. The evaluation parameters include an experimental worthiness threshold value and an activation threshold value for determining whether a symbol pattern associated is worth holding in the working memory, and a degree of certainty threshold value and an abstraction level matching threshold value for determining whether the result satisfies the purpose. They also include a consistency tolerance threshold value for determining whether the plurality of symbol patterns within the working memories are consistent with each other. The setting of these parameters is decided uniquely in accordance with predetermined rules. However, it may be configured such that some correction to the rules is allowed through learning.

When the setting of various parameters based on the intended purpose is completed, symbol patterns to be the sources of association are stored in the working memories (step S120). More specifically, symbol patterns that were associated based on various raw patterns input into the computer in connection with the intended purpose set for the computer are stored in the working memories. Some of these source symbol patterns may have already been stored.

Next, the source symbol pattern within the working memory is selected and sent to the symbol stage (step S130). The pattern to be sent to the symbol stage is selected according to the degrees of activation of the patterns held in the respective working memories and the abstraction levels being represented by parts of the patterns. The ones failing into the symbol category planned at the time of purpose setting and having higher degrees of activation are selected in descending order. Once the selected symbol pattern is sent to the symbol stage and association is performed therewith, the degree of activation with respect to the relevant symbol pattern is decreased by a prescribed value.

When the symbol pattern as the source of association is set on the symbol stage, only the neurons in the fired state are fixed, which are provided to the associative memory and become the boundary condition of association. A plurality of symbols having correlation with the source symbol pattern are associated successively. During the association, the fired state of each neuron within the symbol stage is monitored, and accumulated as the degree of activation. This value is reflected to, e.g., the threshold value of the relevant neuron, so that the likelihood of firing is modulated for each neuron (step S140). In some cases, the degrees of activation of all the neurons are reset to a prescribed value prior to a series of association.

The association with one source symbol pattern is terminated when all the patterns have been associated, or when a prescribed period of time has passed. In each association process, the boundary condition necessary for the association may be set as required with a state pattern signal, by invalidating input/output of the raw neuron group for each associative memory, or by controlling the direction of input/output of the symbol neuron group. When the association with one source symbol pattern is completed, a next source symbol pattern is selected, and the association is carried out in the same manner. The control sequence is repeated until a series of association with all the source symbol patterns is completed (step S150).

When the completion of the series of association with all the source symbol patterns is detected with, e.g., the degree of activation of each working memory, the value judgement network evaluates the symbol pattern ultimately retrieved and placed on the symbol stage. Here, it is first determined whether the retrieved symbol pattern is worth storing in the working memory (step S160). For this value judgement, a degree of activation or a value registered through experience having been embedded within the pattern is compared with a threshold value having been set.

If it is determined that the pattern is unworthy, the process restarts from the storage of a symbol pattern as the source of association in the working memory. At this time, a control may be required to cause only the symbol pattern within the working memory having a low degree of activation to be replaced by a new source symbol pattern.

If it is determined that the pattern is worth storing in the working memory, the symbol pattern within the working memory having the lowest degree of activation is discarded, and the symbol pattern on the symbol stage is stored instead (step S170). At this time, the degree of activation of the relevant working memory is set to a higher value. In this case, it is further determined whether the relevant symbol pattern fulfills the intended purpose (step S180). This determination is made based on whether the abstraction level embedded within the symbol pattern matches the abstraction level of interest, or based on the degree of certainty registered through experience. If it is determined that the pattern is unsatisfactory, the process returns to setting of various parameters or, in some cases, adjustment of the parameters.

If it is determined that the pattern fully satisfies the purpose, it is determined whether the plurality of symbol patterns stored in the working memories are consistent with each other (step S190). If they are contradictory, the process returns to setting of various parameters. If they are consistent, the sequence for action with the outside world via the associative memory based on the symbol patterns within the working memories is carried out, and the computer outputs the answer (step S200). This determination is made using the degree of agreement of correlative neurons included in the respective symbol patterns.

Although the present invention has been described and illustrated in detail, it is clearly understood that the same is by way of illustration only and is not to be taken by way of limitation, the spirit and scope of the present invention being limited only by the terms of the appended claims.

What is claimed is:

1. An associative memory-based computer, comprising at least one associative memory, a plurality of associative data memories capable of temporarily holding input or output data of said associative memory, and a value judgement device receiving part of the data held in said plurality of associative data memories.

2. The associative memory-based computer according to claim 1, wherein said associative memory is formed of a chaotic neural network.

3. The associative memory-based computer according to claim 2, further comprising a function to modulate a threshold value of a neuron forming the associative data in accordance with a fired frequency of the relevant neuron.

4. The associative memory-based computer according to claim 3, wherein the modulation is carried out by decreasing the threshold value of the neuron in proportion to the fired frequency thereof.

5. The associative memory-based computer according to claim 1, wherein said associative data memories include a first associative data memory sending/receiving data directly to/from said associative memory, and a plurality of second associative data memories sending/receiving data to/from said associative memory via said first associative data memory.

6. The associative memory-based computer according to claim 5, further comprising a function to modulate a threshold value of a neuron forming the associative data in accordance with a fired frequency of the relevant neuron.

7. The associative memory-based computer according to claim 6, wherein the modulation is carried out by decreasing the threshold value of the neuron in proportion to the fired frequency thereof.

8. The associative memory-based computer according to claim 5, wherein
said value judgement device receives part of the data in said first associative data memory to evaluate whether an output result associated in the associative memory is a desired result or answers for a purpose, and
an output signal of said value judgement device is used for control of whether to transfer the associative data held in said first associative data memory to said plurality of second associative data memories.

9. The associative memory-based computer according to claim 5, wherein
said value judgement device receives part of the data in said plurality of second associative data memories to evaluate whether a plurality of pieces of associative data held in said plurality of second associative data memories are consistent with each other, and
an output signal from said value judgement device is used for control of whether to transfer the associative data held in said second associative data memories to said first associative data memory.

10. An associative memory-based computer, comprising:
a chaotic associative memory including a raw neuron group as a collection of raw neurons implementing actions with the outside world like sensory organs or muscles, and a symbol neuron group as a collection of symbol neurons serving as sources of information processing within the computer;
a first associative data memory directly connected to the symbol neuron group of said chaotic associative memory and having a function to temporarily hold a symbol pattern represented by states of neuron signals of said symbol neuron group;
a plurality of second associative data memories connected to said first associative data memory and having a function to hold a plurality of patterns of the symbol pattern on said first associative data memory as required;
a first value judgement device receiving some of the signals of said first associative data memory and outputting a signal for determining whether the pattern on said first associative data memory is worth holding on said second associative data memory; and
a second value judgement device receiving part of the data within said second associative data memories and having a function to determine whether the plurality of symbol patterns held in said second associative data memories are consistent with each other.

11. An associative memory-based computer, comprising:
an associative memory portion including a plurality of chaotic associative memories,
each said chaotic associative memory having a symbol neuron group representing an abstractive state and a raw neuron group connected with raw pattern signal inputs from sensory organs like eyes and ears or raw pattern signal outputs to muscles like vocal muscle and those of hands and legs or secretory organs for a specific role to implement an interface with the outside world, and relating a raw pattern from various sensory organs to an abstractive, specific symbol pattern formed based on a common symbol pattern through learning to implement complicated association including correlation between the chaotic associative memories;
a working memory portion including a symbol stage having a function to temporarily store and hold said common symbol pattern, all said specific symbol patterns and a state pattern from said associative memory portion and also having a function to temporally integrate an activation value for each symbol neuron to modulate its firing threshold value in accordance with the integral, a plurality of working memories having a function to hold pattern information held in said symbol stage for a prescribed period of time, and a control sequencer generating a state pattern signal for use in defining directivity of association, invalidation of each input information, invalidation of each associative output, or directivity of each symbol signal in accordance with an external object signal and applying the generated signal commonly to said associative memories; and
a value judgement network portion including a result determination network receiving some of the pattern signals of said symbol stage in said working memory portion and having a function to evaluate at least whether a result associated in said associative memory portion answers for a purpose and thus to determine whether to newly transfer the symbol pattern held to said working memory, and a consistency determination network receiving some of the pattern signals from said working memories and having a function to determine whether a plurality of symbol patterns held in said working memories are consistent with each other, and, according to the value evaluation, to cause a control sequence to develop into an actual operation;
each said symbol neuron group including, between itself and said working memory portion, a portion where a state pattern signal common to all the memories is input, a portion where a common symbol pattern is input/output, and a portion where a specific symbol pattern for each memory is input/output,
said plurality of working memories having a function to have values indicating the degrees of activation for information held in respective said working memories, the degree of activation having a mechanism to be attenuated with a certain time constant and at the same time to be increased/decreased by a prescribed amount in accordance with a condition of said control sequence, and
each of said result determination network and said consistency determination network being formed with a hierarchy-type neural network having a function to improve a value judgement capability through learning, and value signals as outputs from said result determination network and said consistency determination network being applied to the control sequencer in said working memory portion.

12. The associative memory-based computer according to claim 11, wherein said directivity of association indicates whether to abstract or objectify said association.

13. The associative memory-based computer according to claim 11, wherein said directivity of each symbol signal indicates whether said common symbol pattern is an input or output with respect to each said chaotic associative memory.
